(19) United States
(12) Patent Application Publication
(10) Pub. No.: US 2025/0067779 A1
(43) Pub. Date: Feb. 27, 2025

(54) DEVICE FOR MEASURING A CURRENT IN A GROUND CONDUCTOR

(71) Applicant: SUPERGRID INSTITUTE, Villeurbanne (FR)

(72) Inventors: Anaïs LEPROUX, BRON (FR); Martin HENRIKSEN, LYON (FR); Ludovic BOYER, SAINT JOSEPH (FR); Geoffrey RENON, PECHABOU (FR)

(21) Appl. No.: 18/720,812

(22) PCT Filed: Dec. 15, 2022
(86) PCT No.: PCT/EP2022/086101

§ 371 Date: Jun. 17, 2024

(30) Foreign Application Priority Data
Dec. 17, 2021 (FR) FR2113882

(51) Int. Cl. G01R 15/24

(52) U.S. Cl. CPC G01R 15/245

(57) ABSTRACT

The invention relates to a measurement device (1) for measuring a current in at least one cable shield of an electrical transmission grid using the Zeeman effect in the presence of a magnetic field (B_{T}) from the environment, in particular the Earth's magnetic field or magnetic noise, comprising:
at least one assembly of one or more measurement cells (3, 3′),
at least one source of polarized light (7),
at least one polarimetry system (11),
in which
the assembly of one or more measurement cells (3, 3′) is configured so as to define at least one pair of first and second measurement sections (I₁, I₂), the measurement sections (I₁, I₂) of a pair being parallel and arranged perpendicular to a conductor (31) that is connected to the cable shield and on the opposite sides of the conductor (31), the polarized beam of light (9) flowing through the second measurement section (I₂) in the opposite direction with respect to through the first section (I₁) so that the contributions of the magnetic field from the environment to the first parameter in the first and second measurement sections (I₁, I₂) cancel each other out.

The field of the present invention relates to the transmission of electricity in high-voltage alternating current (HVAC) and high-voltage direct current (HVDC) transmission and distribution grids, and more particularly to an electrical energy transmission cable of such a grid, and to an associated device for measuring a magnetic field, or even a current.

The current development of renewable energies is placing new constraints on the electricity grid because the various locations where electricity is produced are generally far from each other and far from the consumption areas. It therefore appears necessary to develop new transmission grids capable of transmitting electricity over very long distances, while at the same time minimizing energy losses.

In order to respond to these constraints, high-voltage (for example 50 kV) direct current (HVDC) grids appear to be a promising solution due to lower line losses than alternating current grids and the lack of occurrence of stray capacitances in the grid over long distances.

In order to control the electrical energy transmission grid, the voltage and/or current are measured at suitable locations on power lines or substations.

To this end, by way of example, inductive transformers formed of a winding surrounding the electrical conductor/electrical energy transmission cable and operating on the principle of electromagnetic induction are known.

However, such known devices do not allow measurements on direct current electrical energy transmission cables.

Also known from WO2019/122693 is a device and method for measuring an electric current in an electric transmission conductor.

In a high-voltage direct current electrical energy transmission grid, at predefined intervals and for safety reasons, a metal shield surrounding the electric power transmission cable is connected to the ground via a grounding conductor.

These grounding conductors are generally arranged at the ends of cables, and in particular at junctions between two cables.

A leakage current flowing through this grounding conductor is generally very low, and depends in particular on the state of the insulation around the electric transmission cable, which may deteriorate over time.

In this way, the leakage current measurement combined with the cable temperature may be used to assess the state of the insulation around the central conductor of the electrical transmission cable, and to prevent, for example, a breakdown and a short-circuit caused by such a breakdown.

The current measurement device known from document WO2019/122693 is at first sight well suited to measuring low currents. However, in this case, the result may be affected by surrounding magnetic fields, such as the Earth's magnetic field or fields originating from nearby infrastructures.

The object of the present invention is to propose a device for measuring the magnetic field induced by a cable shield current, such as in particular a leakage current, and which may eliminate surrounding stray magnetic fields.

To this end, the present invention relates to a device for measuring a current in at least one cable shield of an electrical transmission grid by the Zeeman effect in the presence of a magnetic field from the environment, in particular the Earth's magnetic field or magnetic noise, comprising:
at least one assembly of one or more measurement cells containing a gas sensitive to the Zeeman effect, in particular an alkaline gas,
at least one polarized light source which wavelength is tuned to an absorption line of the gas sensitive to the Zeeman effect and which emits a beam of light through the assembly of one or more measurement cells,
at least one polarimetry system configured so as to measure a first parameter corresponding to the rotation of a polarization angle due to the beam passing through the assembly of one or more measurement cells containing a gas sensitive to the Zeeman effect, and wherein the assembly of one or more measurement cells is configured to define at least one pair of first and second measurement sections, the measurement sections of a pair being parallel and arranged perpendicular to a conductor connected to the cable shield and on opposite sides of the conductor, the polarized beam of light flowing in the second measurement section in the opposite direction to that in the first section so that the contributions of the magnetic field from the environment to the first parameter in the first and second measurement sections cancel each other out, and the contributions of the magnetic field generated by the current in the conductor to the first parameter in the first and second measurement sections are added together.

This configuration therefore eliminates the contribution of external magnetic fields to the measurements and achieves the sensitivity required for the cable shield current measurement. These measurements may therefore be used to monitor or even control the state of the insulation or its change over time between the central conductor and the metal shield in a (very) high-voltage DC or AC electrical transmission grid.

The invention may further comprise one or more of the following aspects taken alone or in combination:

Given that the first parameter is dependent on the temperature prevailing in the measurement cell(s), the device furthermore comprises a processing unit configured to combine the measurement of the first parameter corresponding to the rotation of the polarization angle and a temperature datum to extract a third parameter independent of the temperature prevailing in the measurement cell(s) and corresponding to the current flowing through the cable shield.

The measurement device may additionally comprise a temperature sensor which delivers the temperature datum, the temperature sensor being selectable from the following group: a thermocouple, a temperature probe, a distributed measurement sensor.

The measurement device may also comprise a temperature simulator that outputs the temperature datum.

The measurement device may further comprise at least one absorption measurement system configured to measure a second parameter corresponding to a rate of absorption of the beam by the gas sensitive to the Zeeman effect and to deliver the temperature data.

The alkaline gas is, for example, rubidium, lithium, sodium, potassium, cesium or francium.

The light source may comprise a laser, in particular a laser diode.

In particular, the device comprises optical elements for deflecting the beam of light which are arranged so that the beam of light successively reaches the at least one pair of measurement sections.

Each optical element deflecting the beam of light may be configured to maintain polarization so that the polarization at the input is the same as at the output of the deflecting optical element.

At least one of the optical elements deflecting the beam of light comprises, for example, a deflecting prism or a mirror.

At least one of the optical elements deflecting the beam of light may comprise a polarization-maintaining optical fiber.

The assembly of one or more measurement cells comprises a single measurement cell in the form of a closed container with a central opening configured for the conductor to pass through.

The assembly of one or more measurement cells comprises, for example, a first measurement cell and a second measurement cell for a pair of measurement sections.

The assembly of one or more measurement cells may comprise an assembly of two pairs of first and second measurement cells.

The polarized beam of light and the optical elements deflecting the beam of light are configured so that the beam of light travels at least two turns around the conductor.

The polarized beam of light and the optical elements deflecting the beam of light are configured in such a way that measurement cells of a pair are traversed several times by the beam of light.

According to one example, at least a first pair of measurement sections is associated with a first conductor, and at least one second pair of measurement sections is associated with a second conductor.

The beam of light may travel around the first conductor in the same direction as around the second conductor, so that the measurement result is the sum of the currents flowing through the first and second conductors.

The beam of light may also travel around the first conductor in the direction opposite to the second conductor, so that the result is the difference between the currents flowing in the first and second conductors.

FIG. 1 is an illustrative schematic relating to the polarization of light,

FIG. 2 presents two simplified schematics modelling energy levels of an alkali atom, specifically for part a) in the absence of any electromagnetic field and for part b) in the presence of a magnetic field parallel to the direction of propagation of a beam of light,

FIG. 3 is a simplified schematic of a measurement device according to a first embodiment,

FIG. 4A FIGS. 4A and 4B are explanatory schematics of the magnetic fields present around a grounding conductor,

FIG. 4B

FIGS. 5 to 13 show schematically the arrangement of measurement cell assemblies in different embodiments.

FIG. 6

[symbol]

FIG. 7

[symbol]

FIG. 8

[symbol]

FIG. 9

[symbol]

FIG. 10

[symbol]

FIG. 11

[symbol]

FIG. 12

[symbol]

FIG. 13

[symbol]

In all the figures, elements with identical functions bear the same reference numerals.

The following embodiments are examples. Although the description refers to one or more embodiments, this does not necessarily mean that each reference relates to the same embodiment, or that the features apply only to a single embodiment. Individual features of various embodiments may also be combined or interchanged to provide other embodiments.0

“Upstream” or “downstream” denotes where the elements are located in the direction of propagation of light. Thus, a first apparatus or element is located upstream of a second apparatus or element if the beam of light passes firstly through the first and then through the second apparatus.

The present invention relates to any medium-voltage or high-voltage alternating current or direct current installation, and notably electrical conductors/electrical energy transmission cables or for example air-insulated substations or metal-enclosed substations.

The present invention is applied particularly advantageously in a high-voltage/middle-voltage direct current (HV/MV-DC) or high-voltage/middle-voltage alternating current (HV/MV-AC) network for transmitting electrical energy, i.e. current.

FIG. 1 shows an illustrative schematic relating to the polarization of light. A light wave is an electromagnetic wave which electric field \vec{E} and magnetic field \vec{B} form a direct trihedron with the propagation direction \vec{p_{E}} of this wave. This electric field evolves during the propagation of this wave, describing a specific shape if observed facing the wave. The polarization of the wave (direction of the electric field) during its propagation may thus be classified into 3 categories: rectilinear polarization, circular polarization, and elliptical polarization.

The Zeeman effect is an effect that occurs on the electronic energy levels of atoms (including alkali). These effects may be observed provided that it is possible to interact with these energy levels. One way to interact with these levels is to use the interaction of the electron spins of the atoms in question with photons from resonant light radiation, for example a laser, with the energy level to be interrogated.

The Zeeman effect will then be observable using a linearly polarized light wave interacting with the energy levels involved. This observation is made by monitoring the rotation of linear polarization of the light wave.

This effect may be observed particularly well for example in gases formed from atoms with a single valence electron, such as for example alkali atoms. Alkalis are widely used in many applications due to their single valence electron having a mismatched spin that may be easily manipulated. It is thus possible to approximate the energy of the atom through the energy of the single electron on the valence band.

However, when a gaseous medium is involved, the Zeeman effect depends on the density of the medium through which light passes, and therefore also on the temperature.

Part a) of FIG. 2 shows a simplified schematic modelling energy levels of an alkali atom in the absence of any electromagnetic field.

This entails therefore a simplified three-level energy system (the fundamental sub-level m_{F}=0 is not involved in the atom-laser interaction process that will be described).

This system has a fundamental level that is formed of three fundamental sub-levels of momentum m_{F}=−1, m_{F}=0, and m_{F}=+1. This system also has an excited level without sub-levels of momentum m_{E}=0.

When a linearly polarized light wave with a given direction of propagation propagates, it is possible to break this linear polarization down into the sum of two circular polarizations of opposite direction σ₊ and σ₋.

The light wave will thus interact with the two fundamental sub-levels of momentum m_{F}=−1 and m_{F}=+1 in order to put the electron on the excited level of momentum m_{E}=0. This is explained by a selection rule relating to the conservation of kinetic momentum and the fact that the wave σ₊ exchanges a photon of momentum +1 and the wave σ₋ exchanges a photon of momentum −1.

Part b) of FIG. 2 shows a simplified schematic modelling energy levels of an alkali atom in the presence of a magnetic field \vec{B} parallel to the direction of propagation \vec{p_{E}} of a beam of light.

Applying a magnetic field \vec{B} collinear with the direction of propagation of the light wave \vec{p_{E}} causes an energy displacement of the fundamental sub-levels of momentum m_{F}=−1 and m_{F}=+1 (positive for one and negative for the other, and vice versa in the case of a field in the opposite direction).

In the case of a magnetic field \vec{B} (the Zeeman effect) the value of the energy offset δ_{NRJ}^{\vec{B}} is:

$${δ}_{NRJ}^{\vec{B}} = \vert \vec{{μ}_{B}} \cdot \vec{B} \vert \qquad ( eq . 1 )$$

where \vec{μ_{B}} is the boron magneton.

There is an energy difference of 2*δ_{NRJ}^{\vec{B} in the case of applying a magnetic field between the} 2 fundamental sub-levels of momentum m_{F}=−1 and m_{F}=+1, as may be seen in FIG. 2, part b). This therefore generates a difference between the interaction of the component σ₊ and the component σ₋ with the electrons of the alkali atom considered.

After mathematical reconstruction of the polarization of the light wave, the linear polarization of the light wave having passed through an alkali atom medium of length [symbol] is rotated by an angle θ of:

$${θ}_{\vec{B}} = {ψ}_{\vec{B}} \cdot {n}_{al} \cdot \cdot B \qquad ( eq . 2 )$$

where
ψ_{\vec{B}} is the parameter of interaction between light and matter in the presence of a magnetic field,
B is the component of the magnetic field along the axis of propagation of the light wave \vec{p_{E}},
nₐₗ is the volume density of alkali, which is a temperature-dependent parameter.

It is therefore understood that detecting the rotation of the polarization of the light wave through polarimetry makes it possible to measure a magnetic field when the volume density is known or when it is fixed.

The density of alkaline gas present in a measurement cell is dependent on the temperature (saturation vapor pressure). To overcome this problem, there are several ways of correcting temperature dependence.

One possibility is to place a temperature sensor in the vicinity of the measurement cells, delivering a temperature datum. The temperature in the measurement cell environment may be assumed to be roughly equal to the temperature of the gases in the cell. It is therefore not necessary to place a temperature sensor in the immediate vicinity of the cells. To obtain sufficient temperature data, the sensor may be arranged even at a certain distance of less than 5 m or 1 m, for example.

The temperature sensor may be selected from the following non-limiting group: a thermocouple, a temperature probe, a distributed temperature sensor (known as a DTS system, which uses an optical fiber to measure temperature locally).

Alternatively, the temperature data may come from a temperature simulator. Such a temperature simulator may, for example, estimate the temperature at the measurement cells on the basis of a model taking into account, for example, climate, geography, a thermal model of the cable, the environment.

This simulator may be set up remotely, although it is configured to provide an estimated local temperature at the measurement cells.

Yet another alternative is to use the phenomenon of absorption of the beam of light by the alkaline gas. In fact, the power P_{T} of the beam of light at the output of a measurement cell as a function of the input power P₀ is given by the relationship:

$${P}_{T} = {P}_{0} {e}^{- {ψ}_{Abs} \cdot {n}_{al} \cdot } \qquad ( eq . 3 )$$

where ψ_{Abs} is the parameter of interaction between light and matter due to absorption. Thus:

$$ln ( \frac{{P}_{0}}{{P}_{T}} ) {ψ}_{Abs} \cdot {n}_{al} \cdot \qquad ( eq . 4 )$$

By isolating in this formula nₐₗ:

$${n}_{a} = ln ( \frac{{P}_{0}}{{P}_{T}} ) \frac{1}{{ψ}_{Abs}} \qquad ( eq . 5 )$$

And by using the equation (5) in the equation (2) above, the effect of temperature may be eliminated.

$${θ}_{\vec{B}} = ln ( \frac{{P}_{0}}{{P}_{T}} ) \frac{{ψ}_{\vec{B}}}{{ψ}_{Abs}} \cdot B \qquad ( eq . 6 )$$

For a cylindrical conductor, at a distance R therefrom, the magnetic field B generated by an electric current I flowing through a conductor is given by

$$B = \frac{{μ}_{0}}{2 π R} I \qquad ( eq . 7 )$$

Where μ₀ is the magnetic permeability of the vacuum.

Therefore, by combining the equations (6) and (7), the current flowing through a conductor may be measured by measuring the variation in polarization angle due to the Zeeman effect, eliminating the dependence on temperature.

$$I = ( {θ}_{\vec{B}} * \frac{2 π R}{{μ}_{0}} ) / ( ln ( \frac{{P}_{0}}{{P}_{T}} ) \frac{{ψ}_{\vec{B}}}{{ψ}_{Abs}} \qquad ( eq . 8 )$$

FIG. 3 shows an example of a simplified schematic of a measurement device 1 according to a first embodiment combining both polarimetry and absorption measurement in order to achieve a measurement of the current flowing through a conductor, in particular a ground conductor (leakage current).

The device 1 for measuring a cable shield current of an electrical transmission grid by the Zeeman effect in the presence of a magnetic field from the environment comprises:
at least one assembly of one or more measurement cells 3 containing a gas sensitive to the Zeeman effect, in particular an alkaline gas, and intended to be arranged in a magnetic field indicated by the arrow 5; the assembly of one or more measurement cells 3 is shown in this figure only schematically with a single square,
at least one polarized light source 7 which wavelength is tuned to an absorption line of the gas sensitive to the Zeeman effect contained in the measurement cell 3 and which emits a beam of light 9 passing through said measurement cell 3,
at least one polarimetry system 11 configured to measure a first parameter corresponding to the rotation of a polarization angle caused by the passage of the beam 9 through the assembly of one or more measurement cells 3 enclosing a gas that is sensitive to the Zeeman effect, the first parameter being dependent on the temperature in the assembly of one or more measurement cells 3,
optionally, as discussed above, at least one absorption measurement system 13 configured to measure a second parameter corresponding to an absorption rate of the beam 9 by the gas sensitive to the Zeeman effect, this second parameter being dependent on the temperature, and
a processing unit 15 configured to combine the measurement of the first parameter corresponding to the rotation of the polarization angle and the second parameter corresponding to the absorption rate measured by the absorption measurement system in order to extract therefrom a third parameter independent of the temperature in the assembly of one or more measurement cells and corresponding to the cable shield current.

The gas sensitive to the Zeeman effect contained in the measurement cell 3 is therefore in particular an alkaline gas, for example composed of rubidium, lithium, sodium, potassium, cesium or francium atoms.

The measurement cell(s) of the assembly 3 are in particular transparent to the wavelength of the light source 7 that is used. It is sufficient for only the faces through which the beam of light 9 passes to be transparent. The other surfaces may be opaque, which may be advantageous for eliminating possible interference caused by ambient light.

The measurement cell(s) of the assembly 3 have, as will be detailed later, for example the general shape of a cube, parallelepiped, or cylinder.

The light source 7 is, for example, a laser, in particular a laser diode. The laser wavelength is chosen according to the absorption transition of the chosen alkali. To obtain a polarized light source, it is of course also possible to use a non-polarized light source combined with a polarizer placed on the optical path upstream of the assembly of one or more measurement cells 3.

The polarization of polarized light is for example linear.

The following table gives examples of wavelengths for a given alkali and a given transition.

| Alkali | | Wavelength λ_{D1} (nm) | Wavelength λ_{D2} (nm) |
|---|---|---|---|
| ³⁹K = | Potassium 39 | 770.108 | 766.701 |
| ⁴⁰K = | Potassium 40 | | |
| ⁴¹K = | Potassium 41 | | |
| ⁸⁵Rb = | Rubidium 85 | 794.979 | 780.241 |
| ⁸⁷Rb = | Rubidium 87 | | |
| Cs = | Cesium | 894.593 | 852.347 |

The polarimetry system 11 is in particular a balanced polarimetry system that is arranged downstream of the assembly of one or more measurement cells 3. Such a polarimetric system 11 notably comprises a polarizing beam splitter 17 as well as two associated photodetectors 19 and 21.

The polarizing beam splitter 17 (PBS in the figures) splits the polarization components s and p in order to send them respectively to the photodetectors 19and 21 (PD in the figures), for example photodiodes. For example, the polarization component s is reflected at 90° toward the photodetector 19, whereas the component p passes through the polarizing beam splitter 17 in order to be detected by the photodetector 21.

Thus, by taking into account the measurement signals of the photodetectors 19 and 21, it is possible to measure the polarization angle of the beam of light at the output of the measurement cell 3, and it is possible to determine, knowing the starting linear polarization at the output of the light source 7, the variation in the polarization angle, which makes it possible to determine the value of the current flowing through the conductor(s).

For the sake of simplifying the explanation and without restriction, the situation is assumed in which the input polarization in the measurement cell is at 45° with respect to the component s or p of the polarizing beam splitter 17.

This results in an output signal for the magnetic field \vec{B} along the propagation axis, which is given by:

$${θ}_{B} = {α}_{Att} \cdot \frac{{P}_{1} - {P}_{2}}{{P}_{1} + {P}_{2}} = {ψ}_{\vec{B}} \cdot {n}_{al} \cdot \cdot B \qquad ( eq . 9 )$$

Where
B=the magnetic field component B collinear with the direction of propagation of the beam of light 9,
α_{Att} is the known or predetermined attenuation coefficient of the beam of light,
P₁ is the light intensity measured by the photodetector 19,
P₂ is the light intensity measured by the photodetector 21.

Of course, it is assumed in this case that the beam of light is oriented so as to be substantially perpendicular to the magnetic field.

In order be able to adjust the linear polarization of the beam of light 9 with respect to the polarizing beam splitter 17, a polarizer 22 may be arranged upstream of the assembly of one or more measurement cells 3.

The absorption measurement system 13 will be used to eliminate the dependence on temperature. It comprises an upstream part 13A and a downstream part 13B. In more detail, the upstream part 13A comprises a first beam splitter 23 (BS in the figures), arranged upstream of the assembly of one or more measurement cells 3, and an associated photodetector 25, configured so as to detect the light intensity of the beam of light 9 upstream of the assembly of one or more measurement cells 3. The downstream part 13B comprises a second beam splitter 27, arranged downstream of the measurement cell 3 but upstream of the polarimetry system 11, and an associated photodetector 29, configured so as to detect the light intensity PT of the beam of light 9 downstream of the measurement cell 3.

Alternatively, PT may be determined simply as the sum of

P_{T}=(P₁+P₂)
therefore removing the beam splitter 27 and the photodiode 29 from the assembly shown in FIG. 3. In this case, the light intensity signals P₁ and P₂ measured by the photodiodes 19 and 21 respectively are used to measure both the rotation of a polarization angle and to measure the transmitted light intensity P_{T}.

This temperature-dependent signal may then be corrected with the absorption signal as defined above. The output signal for the magnetic field in equation (9) thus becomes:

$${S}_{\vec{B}} = \frac{{θ}_{\vec{B}}}{ln ( \frac{{P}_{0}}{{P}_{T}} )} = \frac{{ψ}_{\vec{B}}}{{ψ}_{Abs}} \cdot B \qquad ( eq . 10 )$$

The result is a temperature-independent signal that measures the magnetic field and therefore, according to equation (8), the current I flowing through an electrical conductor. In order to find the absolute value B to be measured, a calibration may be used, for example, to determine the correspondence between the measurement signal S and the value of the field B.

In order to trace the electric current flowing in an electrical conductor, it is necessary to take into account the distance between the measurement cell 3 and the electrical conductor.

Given that the alkali atoms are confined within the measurement cell, the absorption rate is ultimately only dependent on the temperature. Using the signal of P_{T} on the photodetector 29 thus also allows for a local measurement of the temperature. In fact, the alkali density nₐₗ is dependent on the temperature T in Kelvin, given by the following relationship:

$${n}_{al} ( T ) = ln ( \frac{{P}_{0}}{{P}_{T}} ) \frac{1}{{ψ}_{Abs}} = \frac{{10}^{18.9848 + a - \frac{b}{T}}}{T} \qquad ( eq . 11 )$$

where parameters a and b are specific to each alkali.

Using a mathematical calculation taking into account the signal P_{T}/P₀, it is therefore possible to measure the local temperature at the same time as measuring the magnetic field.

If, according to the other alternatives described above, the temperature data is obtained, for example, by a measurement via a local or distributed temperature sensor, or by an estimation, the density nₐₗ(T) may be calculated by taking the right-hand side of the equation 11 to take into account the temperature dependence of the rotation signal on the polarization angle.

In FIG. 3, the light source 7 is supplied directly to the optoelectronic assembly.

According to one variant, the light source 7, such as, for example, a laser, is for example remote, the two being connected to one another by an optical fiber.

According to the estimations of the inventors, the leakage current is generally quite low, on the order of 1 mA/km in a high-voltage direct current electrical energy transmission grid.

Under these conditions, measurements may be affected by magnetic fields from the environment, such as, for example, the Earth's magnetic field, which are superimposed on the magnetic field generated by the leakage current flowing through the grounding conductor.

FIG. 4A is an explanatory schematic of the Earth's magnetic field B_{T} and of the magnetic field B_{C} formed around a grounding current conductor 31. This conductor is connected to the cable shield on the one hand, and to an earth or ground terminal on the other.

The magnetic field B_{C} is circular around the conductor 31, while the magnetic field from the environment Br may be considered homogeneous in a single direction and constant at the grounding current conductor 31.

Therefore, if two measurement points P1 and P2 are considered which are equidistant from the grounding current conductor 31 and which are diametrically opposed, the resulting magnetic field Bₜₒₜ (P1) for example at point P1 is the sum of the Earth's magnetic field B_{T} and of the magnetic field B_{C}:

$${B}_{t o t} ( P 1 ) = {B}_{C} + {B}_{T} \qquad ( eq . 12 )$$

while at point P2, the resulting magnetic field Bₜₒₜ (P2) for example at point P2is the difference between the Earth's magnetic fields B_{T} and the magnetic field B_{C}:

$${B}_{t o t} ( P 2 ) = {B}_{C} - {B}_{T} \qquad ( eq . 13 )$$

FIG. 4B is a simplified schematic showing the same electrical conductor 31 in cross-section and the magnetic fields B_{T} and B_{C} formed around an electric current conductor 31. Also indicated schematically are two measurement cells 33-1, 33-2 which are configured to define at least one pair of first and second measurement sections, the measurement sections of a pair being parallel and arranged perpendicular to the conductor 31 and equidistant on opposite sides of the conductor 31, the light flowing in the second measurement section in the opposite direction to that in the first section so that the contributions of the magnetic field from the environment to the first parameter in the first and second measurement sections cancel each other out, and the contributions of the magnetic field generated by the leakage current in the grounding conductor to the first parameter in the first and second measurement sections are added together. A measurement cross-section is defined by the length l traveled by the beam of light 9 in a measurement cell 33 over which the beam of light 9 is in interaction with the gas sensitive to the Zeeman effect. In simplified terms, a measurement section corresponds to the optical path of the beam 9 in a measurement cell 33.

In fact, since the beam of light 9 flows in the second measurement section in the opposite direction to that in the first section, at point P1, due to the presence of the magnetic field from the environment B_{T}, the variation in the polarization angle is greater than that due to the presence of B_{C} alone and varies by Bₜₒₜ (P1)=B_{C}+B_{T}, whereas at point P2, the variation in the polarization angle is smaller than that due to the presence of B_{C} alone and varies by Bₜₒₜ (P2)=B_{C}−B_{T}.

This may therefore be used to eliminate the disturbance induced by the magnetic field from the environment B_{T} by measuring, for example, the change in polarization angle in the measurement cells 33-1 and 33-2. In this case, in the polarization angle change, the contribution of the magnetic field B_{C} is doubled, while that of B_{T} is eliminated.

Consequently, by arranging first and second measurement sections of equal length l symmetrically in pairs with respect to the conductor 31, with light flowing in the second measurement section in the opposite direction to that in the first measurement section, the contribution of the magnetic field from the environment may be eliminated.

As may be seen from the longitudinal orientation of the measurement cells 33-1 and 33-2 shown in FIG. 4B, the light beam 9 is collinear with the magnetic field \vec{B_{C}} in its part passing through the measurement cells 33-1 and 33-2.

FIGS. 5 to 12 show various example embodiments for measurement cells.

### EXAMPLE 1

According to example 1 shown in FIG. 5, two independent polarized beams of light 9-1 and 9-2 are used to measure the change in polarization angle in an arrangement similar to that described in relation to FIG. 3.

In said FIG. 5, a grounding conductor 31 is thus shown, which may have a rectangular, cylindrical, or other cross-section. In said FIG. 5, it is assumed that the current I_{C} to be measured flows perpendicularly through the foil, as shown in the figure. Also shown is a first polarized beam of light 9-1 passing through a measurement cell 33-1 over a length [symbol] ₁ and a second polarized beam of light 9-2 passing through a measurement cell 33-2 over a length [symbol] ₂= [symbol] ₁. The two cells 33-1 and 33-2 forming an assembly of one or more measurement cells 3 are arranged at the same distance R from the conductor 31. Each beam 9-1 and 9-2 is associated with a polarimetry system 11 and an absorption system 13 (not shown in FIG. 5) for measuring the leakage current Ic flowing in the conductor 31.

It is assumed that the alkaline gas used in the measurement cells 33-1 and 33-2 with a measurement cross-section of length [symbol] = [symbol] ₂= [symbol] _{1′} is, for example, rubidium, which is sensitive to the Zeeman effect.

The relationship between the current in Amperes (A) and the polarization angle of rotation θ₁ (angle of rotation in the first cell 33-1) and θ₂ (angle of rotation in the second cell 33-2) for the Zeeman effect may be given by:

$$I = ( {θ}_{1} + {θ}_{2} ) R / ( {A}_{Zeeman} \cdot 2 ℓ \cdot w ) \qquad ( eq . 14 )$$

where
R is the distance between the current conductor 31 and the measurement cells 33-1 and 33-2 in mm,
w is the diameter of the beam of light 9 in the measurement cells 33-1 and 33-2 in mm (diameter is assumed to be constant),
[symbol] is the length of the measurement section of a cell in mm of the part of the beam of light path 9 that is collinear with the magnetic field B.

$$4 \cdot {10}^{- 4} rad . \frac{mm}{{mm}^{2}} / A < {A}_{Zeeman} < 1 , 2 \cdot {10}^{- 3} rad . \frac{mm}{{mm}^{2}} / A ,$$

this range is dependent

on the energy transition chosen for rubidium.

To return to the absolute value of the current I to be measured, a calibration may be used, for example, to determine the correspondence between the measurement signal S and the value of the electric current flowing through the conductor 31.

This provides a reliable and highly sensitive measurement device 1, since the influence of the magnetic fields from the environment B_{T}, notably the Earth's magnetic field, may be eliminated from current measurements. Indeed, in equation (14), for a given measurement device assembly, the current I to be measured varies linearly with the variation in the polarization angle. Due to the chosen assembly 3, the influence of a magnetic field from the environment B_{T} is reduced or even eliminated, and the use of the absorption system 13 makes it possible to eliminate temperature variations.

### Example 2

Example 2 is shown in FIG. 6. As may be seen, the assembly of one or more measurement cells 3 is essentially identical to that shown in FIG. 5, except that a single polarized beam of light 9 from FIG. 5 is used, and optical elements 34-1and 34-2 are used to deflect the beam of light.

According to one example, these may be simple reflectors, mirrors or prisms, which have the effect of turning the angle of rotation by 90°. In this case, the number of reflectors arranged along the optical path traveled must be taken into account when using the measurement signal from the polarimetry system 11 in order to determine the change in the polarization angle due to the Zeeman effect. Of course, this may also be taken into account by a calibration in which the variation in the polarization angle of rotation is measured as a function of a known current flowing through the electrical conductor 31.

Alternatively, the optical elements 34-1 and 34-2 for deflecting the beam of light are polarization-maintaining. These may, for example, be two mirrors or two prisms arranged so that a 90° polarization shift by a first reflector is canceled out by a shift of −90° in the opposite direction by a second reflector. These may also be, for example, polarization-maintaining fibers.

These considerations concerning the optical deflecting elements naturally apply to all the examples described using these optical deflecting elements.

These elements 34-1 and 34-2 are arranged so that the beam of light successively traverses the at least one pair of measurement sections defined respectively by the measurement cells 33-1 and 33-2.

The optical elements 34-1 and 34-2 for deflecting the beam of light comprise, for example, a deflecting prism or a mirror.

This assembly shown in FIG. 6 works in the same way as that shown in FIG. 5.It is simpler because it uses a single balanced polarimetry system 11 and a single absorption system 13.

The complete installation of the measurement device 1 is therefore that shown in FIG. 3, where the assembly of one or more measurement cells 3 shown schematically in FIG. 3 is achieved by the assembly shown in FIG. 6. This also applies to the following examples.

### Example 3

Example 3 is shown in FIG. 7. As may be seen, the assembly of one or more measurement cells 3 is essentially identical to that shown in FIG. 6, except that it comprises a second pair of length measurement sections [symbol] = [symbol] ₃= [symbol] ₄ defined by two additional measurement cells 33-3 and 33-4. An optical element 34-3 is additionally used to deflect the beam of light.

In this assembly, the polarized beam of light 9 makes the turn around the conductor 31 in sections in the same direction (counter-clockwise in the figure) as the orientation of the magnetic field B_{c}, passing successively through the measurement cells 33-1, 33-3, 33-2, and 33-4.

The operation of the embodiment in FIG. 7 is identical to that of FIG. 6. It has the advantage that the total length of the measurement sections is greater, resulting in greater detection sensitivity. Indeed, the interaction length of the laser beam 9 with the gas sensitive to the Zeeman effect is increased, and thus the sensitivity of the measurement device 1 is increased.

### Example 4

Example 4 is shown in FIG. 8. This embodiment is very similar to the embodiment shown in FIG. 7, and differs in particular by a fourth optical element 34-4 for deflecting the beam of light. The four optical elements 34-1, 34-2, 34-3,and 34-4 are, for example, prisms. The optical elements 34-1, 34-2, and 34-3 are of the same size, while the optical element 34-4 is smaller in size to provide an input passage for the polarized beam of light 9 and an output passage. The arrangement of the four optical elements 34-1, 34-2, 34-3, and 34-4 is thus such that the beam of light 9 makes three turns around the conductor 31 (instead of just one turn for the embodiment shown in FIG. 7). Each of the measurement cells 33-1, 33-2, 33-3, and 33-4 is therefore traversed three times, defining three measurement sections. Of course, depending in particular on the size of the measurement cells and the arrangement of the optical deflection elements, the number of turns of the polarized beam of light 9 may also be increased further.

The operation of the embodiment of FIG. 8 is the same as in FIG. 7, but the length of the measurement sections and therefore also the sensitivity is increased by a factor of three.

### Example 5

Example 5 is shown in FIGS. 9 and 10. This embodiment is very similar to the embodiment shown in FIG. 8, as the polarized beam of light makes several turns around the conductor 31 but in a “helical” fashion.

In FIG. 9, the conductor 31 is shown in the form of a bar with a rectangular section. Five measurement cells 33 are above the conductor 31, five below, five on one side, and five on the opposite side. The measurement device 1 therefore has a total of ten pairs of measurement sections (five pairs parallel to the long side of the cross-section of the conductor 31 and five pairs parallel to the short side of the cross-section of the conductor 31). The polarized beam of light travels between the measurement cells via optical deflector elements 34′, formed somewhat like a periscope by two prisms or mirrors, for example, the first of which deflects the beam of light in a direction parallel to the conductor 31 and a second of which deflects the beam of light in a direction perpendicular to the conductor 31 towards a next measurement cell 31. This is also shown schematically in 3D in FIG. 10.

The operation in this embodiment is identical to FIG. 8, but with 5 turns of the beam around the conductor 31 instead of three, and therefore even greater sensitivity.

### Example 6

Example 6 is shown in FIG. 11. This embodiment is very similar to the embodiment shown in FIG. 7.

Contrary to FIG. 7, the assembly of one or more measurement cells 3 comprises a single measurement cell 33 in the form of a closed container with transparent walls (at least to allow the beam of light 9 to pass in and out) and a central opening 37 configured for the grounding conductor 31 to pass through.

The three optical deflecting elements 34-1, 34-2, and 34-3 are obtained as deflecting cubes which are placed inside the container containing the gas sensitive to the Zeeman effect.

The operation of this embodiment is identical to that of FIG. 7.

According to one development, for example, the walls of the container may be made opaque, and the beam of light 9 may be conveyed using an optical fiber, which one end is positioned in front of a laser and which other end opens into the interior of the container. For the output, an output optical fiber with a collimator may also be used to supply the beam of light 9 to the optical fiber, which one input opens into the container and the output conveys the polarized light to the respective detectors of the polarimetry and absorption systems.

### Example 7

Example 7 is shown schematically in FIG. 12.

This embodiment is very similar to the embodiment shown in FIG. 7.

In particular, a first electrical conductor 31 associated with a first assembly of one or more measurement cells 3, which is identical to that shown in FIG. 7, and a second electrical conductor 31′ associated with a second assembly of one or more measurement cells 3′, which is also identical to that shown in FIG. 7, are shown. For the assembly of one or more measurement cells 3′, the references have been labeled with an apostrophe “′”. Thus, for example, the measurement cell 33′-1 is located close to the electrical conductor 31′ and is identical in structure to the measurement cell 33-1.

The advantage is that the same polarized beam of light 9 is used for both measurement cell assemblies 3 and 3′ in series, as well as a single polarimetry system 11 and a single absorption system 13. To this end, a deflecting optical element 34-5 deflects the beam of light 9 exiting the assembly 3 towards the input of the assembly 3′.

For both measurement cell assemblies 3 and 3′ in series, the polarized beam of light 9 travels in the same direction, e.g. counter-clockwise.

In this case, the measurement result is the sum of the contributions of the two measurement cell assemblies 3 and 3′ in series. Thus, a single polarized beam of light 9 emitted by a single light source 7 may be used to measure the sum of leakage currents (I_{C}+I_{C}′) flowing in conductors 31 and 31′ respectively.

Such an assembly is advantageous, for example, when the leakage current must be measured in several electrical grounding conductors. This is generally the case in grounding boxes for high-voltage AC and DC transmission and distribution grids.

By carefully selecting the thresholds not to be exceeded, it is therefore possible to monitor the leakage current in several electrical conductors at the same time using a reduced number of measurement sensors, in particular photodiodes PD.

### Example 8

Example 8 is shown schematically in FIG. 13.

This embodiment is very similar to the embodiment shown in FIG. 12.

In particular, a first electrical conductor 31 associated with a first assembly of one or more measurement cells 3, which is identical to that shown in FIG. 7, and a second electrical conductor 31′ associated with a second assembly of one or more measurement cells 3′, which is also identical to that shown in FIG. 7, are shown. For the assembly of one or more measurement cells 3′, the references have been labeled with an apostrophe “′”. Thus, for example, the measurement cell 33′-1 is located close to the electrical conductor 31′ and is identical in structure to the measurement cell 33-1.

The advantage is that the same polarized beam of light 9 is used for both measurement cell assemblies 3 and 3′ in series, as well as a single polarimetry system 11 and a single absorption system 13. To do this, a deflecting optical element 34-5 deflects the beam of light 9 exiting the assembly 3 towards the input of the assembly 3′.

However, unlike FIG. 12, for the two measurement cell assemblies 3 and 3′ in series, the polarized beam of light 9 travels in the opposite direction, for example counter-clockwise for the assembly 3 and clockwise for the assembly 3′. A deflecting optical element 34′-5 deflects, for example, the beam of light 9 exiting the assembly 3′ towards the sensors of the polarimetry system 11 and of the absorption measurement system 13.

In this case, the measurement result is the difference in contribution of the two measurement cell assemblies 3 and 3′ in series. Thus, a single polarized beam of light emitted by a single light source 7 may be used to measure the difference in leakage currents (I_{C}-I_{C}′) flowing in conductors 31 and 31′ respectively.

Such an arrangement is advantageous, for example, when a leakage current differential has to be measured in several electrical conductors at the same time. This is generally the case in grounding boxes for high-voltage AC and DC transmission and distribution grids.

By carefully selecting the thresholds not to be exceeded, it is therefore possible to monitor the leakage current in several electrical conductors at the same time using a reduced number of measurement sensors, in particular photodiodes PD.

It is therefore clear that the present invention makes it possible to measure low currents in the electrical conductors using the Zeeman effect, while at the same time eliminating magnetic fields from the environment, such as the Earth's magnetic field.

1. A measurement device (1) for measuring a current in at least one cable shield of an electrical transmission grid by the Zeeman effect in the presence of a magnetic field from the environment (B_{T}), in particular the Earth's magnetic field or magnetic noise, comprising:
at least one assembly of one or more measurement cells (3, 3′) containing a gas sensitive to the Zeeman effect, in particular an alkaline gas,
at least one polarized light source (7) which wavelength is tuned to an absorption line of the gas sensitive to the Zeeman effect and which emits a beam of light (9) through the assembly of one or more measurement cells (3, 3′),
at least one polarimetry system (11) configured to measure a first parameter corresponding to the rotation of a polarization angle as a result of the beam (9) passing through the assembly of one or more measurement cells (3, 3′) containing a gas sensitive to the Zeeman effect,
and
wherein
the assembly of one or more measurement cells (3, 3′) is configured to define at least one pair of first and second measurement sections (I1, I2; I3, I4; I′1, I′2; I′3,I′4), the measurement sections (I1, I2; I3, I4; I′1, I′2; I′3, I′4) of a pair being parallel and arranged perpendicular to a conductor (31, 31′) connected to the cable shield and on opposite sides of the conductor (31, 31′), the polarized beam of light (9) flowing in the second measurement section (I2; I4; I′2; I′4) in the opposite direction to that in the first section (I1, I3; I′1, I′3) in such a way that the contributions of the magnetic field from the environment to the first parameter in the first and second measurement sections (I1, I2; I3, I4; I′1, I′2; I′3, I′4) cancel each other out, and the contributions of the magnetic field generated by the current in the conductor to the first parameter in the first and second measurement sections are added together (I1, I2; I3, I4; I′1, I′2; I′3, I′4), the variation in the polarization angle making it possible to determine the value of the current flowing through the conductor (31, 31′).

2. The measurement device as claimed in claim 1, the first parameter being dependent on the temperature prevailing in the measurement cell(s) (3), wherein the device further comprises a processing unit (15) configured to combine the measurement of the first parameter corresponding to the rotation of the polarization angle and a temperature datum in order to extract therefrom a third parameter independent of the temperature prevailing in the measurement cell(s) and corresponding to the current flowing through the cable shield.

3. The measurement device as claimed in claim 2, further comprising a temperature sensor delivering the temperature datum, the temperature sensor being selectable from the following group: a thermocouple, a temperature probe, a distributed measurement sensor.

4. The measurement device as claimed in claim 2, further comprising a temperature simulator delivering the temperature datum.

5. The measurement device as claimed in claim 2, further comprising at least one absorption measurement system (13) configured to measure a second parameter corresponding to a rate of absorption of the beam (9) by the gas sensitive to the Zeeman effect, and to output the temperature datum.

6. The measurement device as claimed in claim 1, wherein the alkaline gas is rubidium, lithium, sodium, potassium, cesium or francium.

7. The device as claimed in claim 1, wherein the light source (7) comprises a laser, in particular a laser diode.

8. The device as claimed in claim 1, wherein it comprises optical deflection elements (34-1, 34-2, 34-3, 34-4,34-5; 34′-1, 34′-2, 34′-3, 34′-4, 34′-5) of the beam of light (9), which are arranged so that the beam of light (9) successively reaches the at least one pair of measurement sections (I1, I2; I3, I4; I′1, I′2; I′3, I′4).

9. The device as claimed in claim 1, wherein each deflecting optical element (34-1, 34-2, 34-3, 34-4, 34-5; 34′-1, 34′-2, 34′-3, 34′-4, 34′-5) of the beam of light (9) is configured to maintain the polarization such that the polarization at the input is the same as at the output of the deflecting optical element (34-1, 34-2, 34-3, 34-4, 34-5; 34′-1, 34′-2, 34′-3,34′-4, 34′-5).

10. The device as claimed in claim 1, wherein at least one of the optical deflecting elements (34-1, 34-2, 34-3, 34-4,34-5; 34′-1, 34′-2, 34′-3, 34′-4, 34′-5) of the beam of light (9) comprises a deflecting prism or mirror.

11. The device as claimed in claim 1, wherein at least one of the optical deflection elements (34-1, 34-2, 34-3, 34-4,34-5; 34′-1, 34′-2, 34′-3, 34′-4, 34′-5) of the beam of light (9) comprises a polarization-maintaining optical fiber.

12. The device as claimed in claim 1, wherein the assembly of one or more measurement cells (3) comprises a single measurement cell (3) in the form of a closed container, having at the center an opening (37) configured for the conductor (31) to pass through.

13. The device as claimed in claim 1, wherein the assembly of one or more measurement cells (3,3′) comprises, for a pair of measurement sections (I1, I2; I3, I4; I′1, I′2; I′3, I′4), a first measurement cell (33-1; 33-3; 33′-1; 33′-3) and a second measurement cell (33-2; 33-4; 33′-2; 33′-4).

14. The device as claimed in claim 13, wherein the assembly of one or more measurement cells (3, 3′) comprises an assembly of two pairs of first and second measurement cells (33-1, 33-2; 33-3, 33-4; 33′-1, 33′-2; 33′-3,33′-4).

15. The device as claimed in claim 8, wherein the polarized beam of light (9) and the deflecting optical elements (34-1, 34-2, 34-3, 34-4) of the beam of light are configured so that the beam of light (9) travels at least two turns around the conductor (31, 31′).

16. The device as claimed in claim 15, wherein the polarized beam of light (9) and the deflecting optical elements (34-1, 34-2, 34-3, 34-4, 34-5;34′-1, 34′-2, 34′-3, 34′-4, 34′-5) of the beam of light are configured in such a way that a pair of measurement cells (33-1, 33-2, 33-3, 33-4) are traversed several times by the beam of light (9).

17. The device as claimed in claim 15 wherein at least a first pair of measurement sections (I1, I2; I3, I4) is associated with a first conductor (31) and at least a second pair of measurement sections (I′1, I′2; I′3, I′4) is associated with a second conductor (31′).

18. The device as claimed in claim 17 wherein the beam of light (9) travels around the first conductor (31) in the same direction as around the second conductor (31′) so that the measurement result is the sum of the currents flowing through the first (31) and second (31′) conductors.

19. The device as claimed in claim 17 wherein the beam of light travels around the first conductor (31) in the opposite direction to the second conductor (31′), so that the result is the difference between the currents flowing through the first (31) and second (31′) conductors.
